(19) United States
(12) Patent Application Publication
(10) Pub. No.: US 2008/0218979 A1
(43) Pub. Date: Sep. 11, 2008

(54) Printed circuit (PC) board module with improved heat radiation efficiency

(76) Inventor: Jong-Ho Park, Suwon-si (KR)

Correspondence Address: ROBERT E. BUSHNELL, 1522 K STREET NW, SUITE 300, WASHINGTON, DC, 20005-1202, US

(21) Appl. No.: 11/979,462

(22) Filed: Nov. 2, 2007

(30) Foreign Application Priority Data
Mar. 8, 2007 (KR) 10-2007-0023096

(51) Int. Cl. H05K 7/20

(52) U.S. Cl. 361/712

(57) ABSTRACT

A Printed Circuit (PC) board module is structured such that heat generated by an Integrated Circuit (IC) device can be sufficiently radiated to the outside. The PC board module includes: a first PC board having a first conductive ground pad arranged therein; a plurality of via holes contained within the first PC board and positioned below the first ground pad; a plurality of conductive via lines contained within the plurality of via holes; a second PC board arranged below the first PC board; and a second conductive ground pad arranged on the second PC board and contacting the plurality of via lines.

### CLAIM OF PRIORITY

This application makes reference to, incorporates the same herein, and claims all benefits accruing under 35 U.S.C.§119 from an application for PRINTED CIRCUIT BOARD MODULE WITH IMPROVED HEAT RADIATION EFFICIENCY earlier filed in the Korean Intellectual Property Office on 8 Mar. 2007 and there duly assigned Serial No. 10-2007-0023096.

### BACKGROUND OF THE INVENTION

1. Field of the Invention

The present invention relates to a Printed Circuit (PC) board module, and more particularly, the present invention relates to a PC board module with improved heat radiation efficiency.

2. Description of the Related Art

Several thousands to several millions of circuit elements, such as transistors, capacitors, and resistors, are formed in an Integrated Circuit (IC) device. The IC device performs various functions as the circuit elements transmit or receive signals. The IC device can process more signals as more circuit elements are formed in the IC device.

An IC device generates more heat during operation as the amount of signal processing increases or when an operating voltage increases, thereby making the operation of internal circuit elements of the IC device unstable, and in serious cases, causing a malfunction of the internal circuit elements.

In particular, when an IC device mounted on a PC board generates a large amount of heat, other circuit elements may be affected by the IC device, and thus, a PC board module may be discarded as being defective. Thus, in order to stabilize a PC board module, it is necessary to sufficiently radiate heat generated by an IC device mounted on a PC board.

Therefore, various attempts have been made to sufficiently radiate heat generated by an IC device mounted on a PC board. However, a more effective method is needed.

### SUMMARY OF THE INVENTION

The present invention provides a PC board module which is structured such that heat generated by an IC device on the PC board can be sufficiently radiated to the outside.

According to one aspect of the present invention, a Printed Circuit (PC) board module is provided, the module including: a first PC board having a conductive first ground pad arranged thereon; a plurality of via holes arranged within the first PC board and positioned below the first ground pad; a plurality of conductive via lines contained within the plurality of via holes; a second PC board arranged below the first PC board; and a second conductive ground pad arranged on the second PC board and contacting the plurality of via lines.

The PC board module may further include an Integrated Circuit (IC) device arranged on the first ground pad. The IC device may include an IC chip therein, and the PC board module may further include a ground plate attached to a lower surface of the IC chip and connected to a ground terminal of the IC chip, a lower surface of the ground plate being exposed outside of the IC device. The ground plate may be attached to the first ground pad with an adhesive. The adhesive may include a conductive adhesive.

The plurality of via lines may be electrically connected to the first ground pad and the second ground pad.

The PC board module may further include an intermediate insulator interposed between the first PC board and the second PC board to insulate the first PC board from the second PC board. The PC board module may further include a plurality of other via lines contained within the intermediate insulator to electrically connect the plurality of via lines arranged within the first PC board to the second ground pad.

The intermediate insulator may include a Pressure Conductive Rubber (PCR), and a portion of the intermediate insulator may become conductive when pressed.

The first ground pad may have a wider area than that of the IC device.

According to another aspect of the present invention, a Printed Circuit (PC) board module is provided, the module including: a PC board having a conductive first ground pad arranged thereon; a plurality of via holes contained within the PC board and positioned below the first ground pad; a plurality of conductive via lines contained within the plurality of via holes; and a second ground pad arranged below the PC board and contacting the plurality of via lines.

The first ground pad may have a wider area than that of the second ground pad.

The plurality of via lines may include solder.

The PC board module may further include an Integrated Circuit (IC) device arranged on the first ground pad. The IC device may include an IC chip therein, and the PC board module may further include a ground plate attached to a lower surface of the IC chip and connected to a ground terminal of the IC chip, a lower surface of the ground plate being exposed outside of the IC device. The ground plate may be attached to the first ground pad with a conductive adhesive.

### BRIEF DESCRIPTION OF THE DRAWINGS

A more complete appreciation of the present invention and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a sectional view of a PC board module according to an embodiment of the present invention;

FIG. 2 is a plan view of the PC board module of FIG. 1;

FIG. 3 is a plan view of the PC board module of FIG. 1 from which an IC device has been removed;

FIG. 4 is a sectional view of an IC device of FIG. 1;

FIG. 5 is a sectional view of a PC board module according to another embodiment of the present invention;

FIG. 6 is a sectional view of a PC board module according to still another embodiment of the present invention;

FIG. 7 is a sectional view of a PC board module according to yet another embodiment of the present invention; and

FIG. 8 is a sectional view of a structure wherein an insulating layer is attached to a lower surface of a PC board of FIG. 7.

### DETAILED DESCRIPTION OF THE INVENTION

The present invention is described more fully below with reference to the accompanying drawings, in which exemplary embodiments of the present invention are shown. The same reference numerals refer to the same constitutional elements throughout the specification.

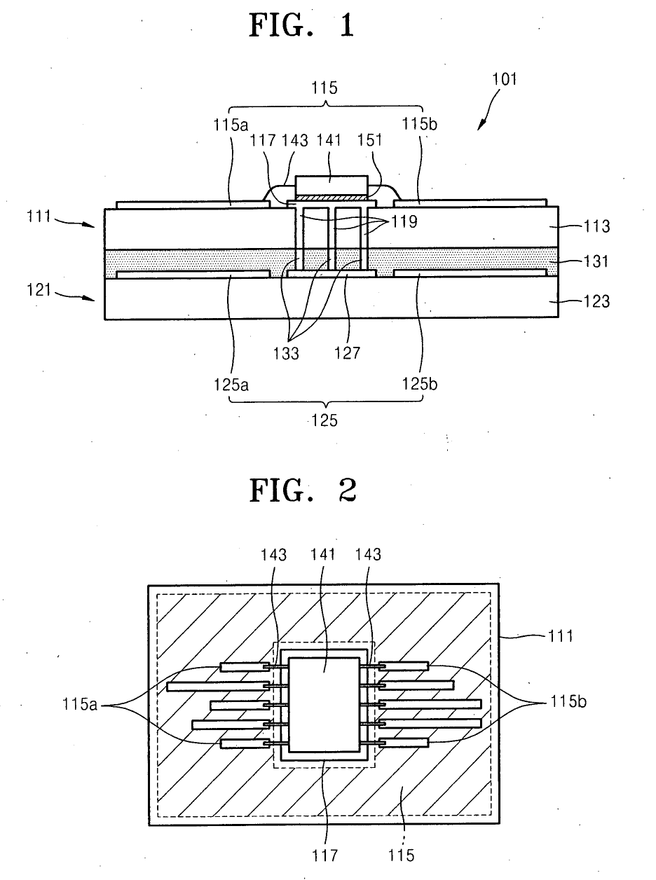

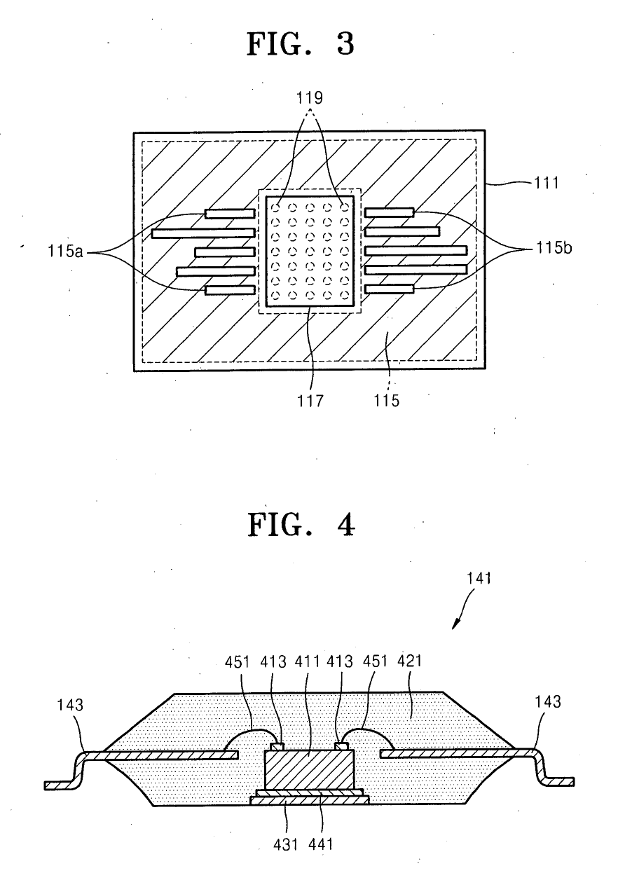

FIG. 1 is a sectional view of a PC board module according to an embodiment of the present invention, FIG. 2 is a plan view of the PC board module of FIG. 1, and FIG. 3 is a plan view of the PC board module of FIG. 1 from which an IC device has been removed.

Referring to FIGS. 1 through 3, a PC board module 101 includes a first PC board 111, a second PC board 121, an intermediate insulator 131, and an IC device 141.

The first PC board 111 includes a first substrate 113, a first metal line portion 115, a first ground pad 117, and a plurality of via lines 119.

The first substrate 113 is made of an insulating material, e.g., a ceramic or resin.

The first metal line portion 115 is disposed on the first substrate 113. The first metal line portion 115 includes a plurality of metal lines 115a and 115b. The metal lines 115a and 115b are made of a conductive material, e.g., copper. The metal lines 115a and 115b electrically connect circuit devices (not shown) mounted on the first substrate 113, including the IC device 141.

The first ground pad 117 is disposed on the first substrate 113. The first ground pad 117 is made of the same material as the metal lines 115a and 115b, e.g., copper. The first ground pad 117 may have various shapes. Preferably, the first ground pad 117 may have the same tetragonal shape as the IC device 141. The IC device 141 is mounted on the first ground pad 117. The first ground pad 117 reinforces the heat radiation and grounding efficiencies of the IC device 141.

The IC device 141 contains an IC chip therein (see 411 of FIG. 4). Heat coming from the IC device 141 is substantially generated by the IC chip. When the PC board module 101 operates, the IC device 141 operates. Heat is generated by the IC device 141. The heat generated by the IC device 141 is transmitted to the first ground pad 117. The first ground pad 117 has a wider area than the IC device 141. That is, when the IC device 141 is mounted on the first ground pad 117, the first ground pad 117 is partially exposed out of the IC device 141. As such, since the first ground pad 117 is partially exposed out of the IC device 141, heat transmitted to the first ground pad 117 from the IC device 141 is radiated into the air. Thus, the IC device 141 is protected from thermal damage. However, when a large amount of heat is generated by the IC device 141, the first ground pad 117 alone cannot timely radiate all of the heat generated by the IC device 141. In this case, a second ground pad 127 disposed on the second PC board 121 reinforces the heat radiation efficiency of the IC device 141.

When the IC device 141 is mounted on the first ground pad 117, a ground plate (see 431 of FIG. 4) of the IC device 141 is connected to the first ground pad 117. As such, when the ground plate of the IC device 141 is connected to the first ground pad 117, a grounding area of the IC device 141 is increased, thereby enhancing the grounding efficiency of the IC device 141.

The via lines 119 are disposed below the first ground pad 117. In order to form the via lines 119, a plurality of via holes are formed in the first substrate 113 to be positioned below the first ground pad 117 and are then filled with a conductive material, e.g., solder or copper.

The intermediate insulator 131 is made of an insulating material and is interposed between the first PC board 111 and the second PC board 121. Thus, the first PC board 111 and the second PC board 121 are electrically insulated by the intermediate insulator 131. A plurality of via lines 133 are formed in the intermediate insulator 131. That is, a plurality of via holes are formed in the intermediate insulator 131 in such a manner that they correspond to the via lines 119 formed in the first substrate 113, and are then filled with a conductive material so as to form the via lines 133 in the intermediate insulator 131.

The second PC board 121 includes a second substrate 123, a second metal line portion 125, and the second ground pad 127.

The second substrate 123 is made of an insulating material, e.g., a ceramic or resin.

The second metal line portion 125 is disposed on the second substrate 123 and is comprised of a plurality of metal lines 125a and 125b. The metal lines 125a and 125b are made of a conductive material, e.g., copper. The second metal line portion 125 can be electrically connected to the first metal line portion 115 via other via lines (not shown) formed in the first substrate 113. The second metal line portion 125 is not required but is optional.

The second ground pad 127 is disposed on the second substrate 123. The second ground pad 127 is arranged to vertically correspond to the first ground pad 117. The second ground pad 127 is made of the same material as the metal lines 125a and 125b of the second metal line portion 125, e.g., copper. The second ground pad 127 may have various shapes. Preferably, the second ground pad 127 may have a similar shape to the first ground pad 117.

As described above, when the second ground pad 127 is electrically connected to the first ground pad 117, an area for heat radiation of the IC device 141 is increased. That is, heat generated by the IC device 141 is transmitted to the first ground pad 117 and the second ground pad 127 via the via lines 119 and 133, and is then rapidly radiated into the air. Thus, even when a large amount of heat is generated by the IC device 141, all of the heat is radiated into the air via the first ground pad 117 and the second ground pad 127 without affecting the operation of the IC device 141. Therefore, it is possible to protect the IC device 141 from thermal damage.

Moreover, when the second ground pad 127 is electrically connected to the first ground pad 117, a grounding area of the IC device 141 extends to the first ground pad 117 and the second ground pad 127. That is, the grounding area of the IC device 141 is enlarged. As the grounding area of the IC device 141 increases, the grounding efficiency of the IC device 141 is significantly enhanced. Thus, when an external surge voltage is applied to a ground terminal of the IC device 141, both the first ground pad 117 and the second ground pad 127 can absorb the surge voltage, thereby preventing damage to the IC device 141 due to the surge voltage.

The IC device 141 includes a plurality of leads 143 protruding outward, and the leads 143 are connected to the first metal line portion 115. Thus, the IC device 141 transmits/receive signals to/from circuit elements (not shown) disposed on the first metal line portion 115. The IC device 141 is attached to the first ground pad 117 with an adhesive 151 (e.g., epoxy). Thus, the IC device 141 is electrically connected to the first ground pad 117. The adhesive 151 is conductive. The structure of the IC device 141 is described in more detail below with reference to FIG. 4.

FIG. 4 is a sectional view of the IC device 141 of FIG. 1.

Referring to FIG. 4, the IC device 141 includes an IC chip 411 therein, and the IC chip 411 is sealed by a molding material 421. The molding material 421 is an insulator. A plurality of electrode pads 413 are formed on the IC chip 411. The electrode pads 413 are connected to one end of each of a plurality of leads 143 via bonding metal lines 451. A ground plate 431 is attached to a lower surface of the IC chip 411. The ground plate 431 is attached to the IC chip 411 with an adhesive 441. The ground plate 431 is conductive. A lower surface of the ground plate 431 is exposed out of the IC device 141. The ground plate 431 is connected to a ground terminal of the IC chip 411.

As described above, when the ground plate 431 is connected to the lower surface of the IC chip 411, the grounding efficiency of the IC chip 411 is reinforced. Moreover, since the ground plate 431 is exposed out of the IC device 141, heat generated by the IC chip 411 is radiated out of the ground plate 431, thereby protecting the IC chip 411 from thermal damage.

The heat radiation effect is more significant, in particular, when the IC chip 411 is a regulator or a Central Processing Unit (CPU) that generates a large amount of heat during operation.

The leads 143 are connected to the IC device 141. However, a plurality of other connectors, e.g., a plurality of bumps or conductive balls, may be substituted for the leads 143.

The structure of the IC device 141 can be changed.

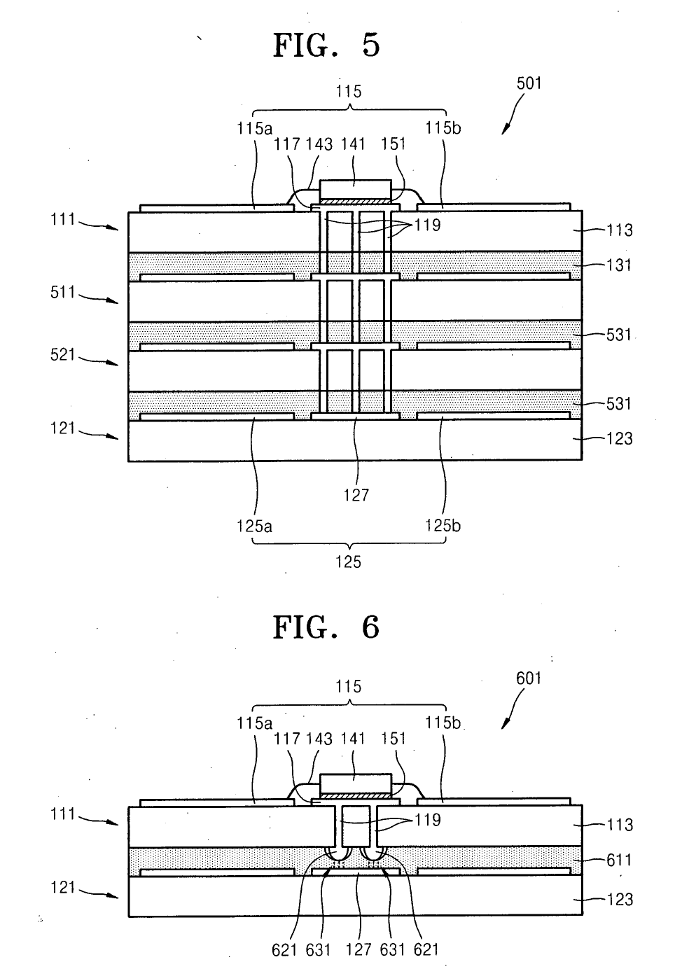

FIG. 5 is a sectional view of a PC board module according to another embodiment of the present invention.

Referring to FIG. 5, a PC board module 501 includes a plurality of PC boards 111, 511, 521, and 121, a plurality of intermediate insulators 131 and 531, and an IC device 141. That is, the PC board module 501 is different from the PC board module 101 of FIG. 1 in that the PC boards 511 and 521 are further interposed between the PC boards 111 and 121. The intermediate insulators 131 and 531 are interposed between the PC boards 111, 511, 521, and 121 to electrically insulate the PC boards 111, 511, 521, and 121. The intermediate insulators 131 and 531 are as described above with reference to FIG. 1.

As described above, as the number of stacked PC boards increases, the heat radiation and grounding efficiencies of an IC device are further enhanced. That is, the heat radiation and grounding efficiencies of an IC device are enhanced proportionally to an increase in the number of stacked PC boards.

FIG. 6 is a sectional view of a PC board module according to still another embodiment of the present invention.

Referring to FIG. 6, a PC board module 601 includes a first PC board 111, a second PC board 121, an intermediate insulator 611, and an IC device 141. The PC board module 601 is different from the PC board module 101 of FIG. 1 only in terms of the intermediate insulator 611 and a plurality of protrusions 621. Thus, in order to avoid overlapping descriptions, the current embodiment of the present invention is described below only in terms of the intermediate insulator 611 and the protrusions 621.

The protrusions 621 are formed to protrude from a lower surface of the first PC board 111. The protrusions 621 are connected to a plurality of via lines 119 formed in the first PC board 111.

The intermediate insulator 611 is interposed between the first PC board 111 and the second PC board 121. The intermediate insulator 611 is an insulator, but when pressed, pressed portions 631 become conductive. That is, when the intermediate insulator 611 is interposed between the first PC board 111 and the second PC board 121, the portions 631 of the intermediate insulator 611 are pressed by the protrusions 621. Thus, the protrusions 621 are electrically connected to a second ground pad 127. Preferably, the intermediate insulator 611 may be made of Pressure Conductive Rubber (PCR).

As described above, the intermediate insulator 611 becomes conductive when pressed, and thus, it is not necessary to form a plurality of via lines (see 133 of FIG. 1) in the intermediate insulator 611. Thus, when one of the first PC board 111 and the second PC board 121 is defective, it is very easy to replace the defective PC board with a new one. That is, according to the current embodiment of the present invention, it is easy to repair a defective PC board module.

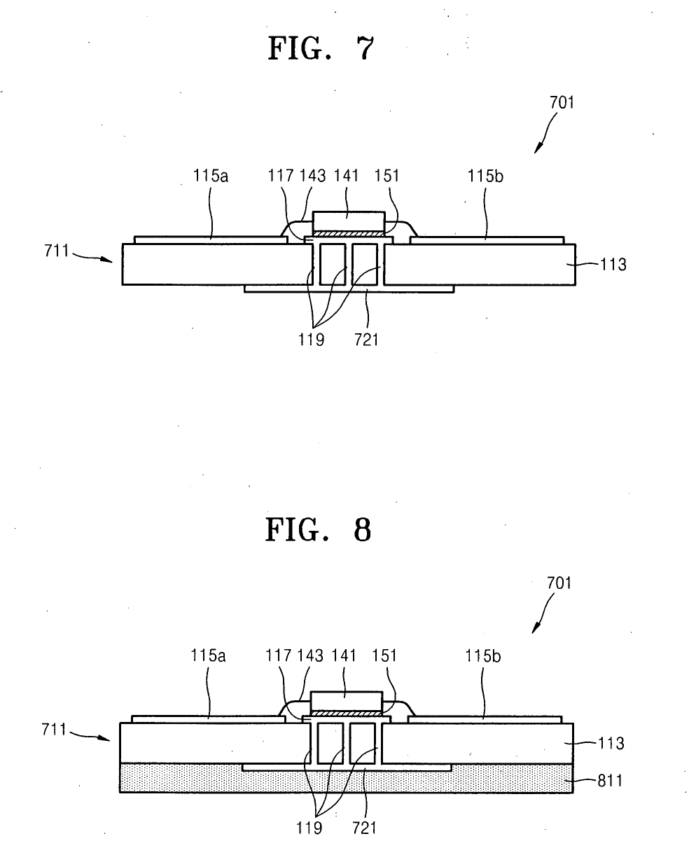

FIG. 7 is a sectional view of a PC board module according to yet another embodiment of the present invention.

Referring to FIG. 7, a PC board module 701 includes a PC board 711 and an IC device 141. The PC board module 701 is different from the PC board module 101 of FIG. 1 in that a second ground pad 721 is used instead of the second PC board 121 of FIG. 1. Thus, only the second ground pad 721 is described hereinafter.

The second ground pad 721 is disposed on a lower surface of the PC board 711. The second ground pad 721 is electrically connected to a plurality of via lines 119. The second ground pad 721 is made of a conductive material, e.g., copper or lead. The second ground pad 721 may have various shapes, e.g., a tetragonal or circular shape. As the size of the second ground pad 721 increases, the above-described effect can be more efficiently achieved.

The second ground pad 721 reinforces the heat radiation and grounding efficiencies of the IC device 141 mounted on a first ground pad 117. That is, heat generated in the IC device 141 is transmitted to the second ground pad 721 via the first ground pad 117 and is then rapidly radiated into the air. Therefore, the IC device 141 can be protected from thermal damage.

Moreover, due to further installation of the second ground pad 721, the grounding area of the IC device 141 extends to the first ground pad 117 and the second ground pad 721. That is, the grounding area of the IC device 141 is enlarged. As the grounding area of the IC device 141 increases, the grounding efficiency of the IC device 141 is significantly enhanced. Thus, an external surge voltage applied to a ground terminal of the IC device 141 is completely absorbed in the first ground pad 117 and the second ground pad 721, thereby preventing damage to the IC device 141 due to the surge voltage.

FIG. 8 is a sectional view of the PC board 711 of FIG. 7 having an insulating layer 811 on a lower surface thereof. Referring to FIG. 8, together with FIG. 7, the insulating layer 811 is attached to the lower surface of the PC board 711. Thus, it is possible to protect the second ground pad 721 disposed on a lower surface of the PC board 711 from an ambient environment.

As described above, according to the present invention, a plurality of via lines are formed in a PC board on which an IC device is mounted, and a plurality of ground pads are connected to the IC device via the via lines. Thus, the heat radiation efficiency of the IC device is significantly enhanced, thereby preventing damage to the IC device due to heat generated in the IC device.

Moreover, due to the above-described structural characteristics, the grounding area of the IC device is significantly increased. As such, as the grounding area of the IC device increases, an external surge voltage applied to the IC device is completely absorbed in the ground pads. Therefore, it is possible to prevent damage to the IC device due to the surge voltage.

While the present invention has been particularly shown and described with reference to exemplary embodiments thereof, it will be understood by those of ordinary skill in the art that various modifications in form and detail may be made therein without departing from the spirit and scope of the present invention as defined by the following claims.

What is claimed is:

1. A Printed Circuit (PC) board module comprising:
a first PC board having a conductive first ground pad arranged thereon;
a plurality of via holes arranged within the first PC board and positioned below the first ground pad;
a plurality of conductive via lines contained within the plurality of via holes;
a second PC board arranged below the first PC board; and
a second conductive ground pad arranged on the second PC board and contacting the plurality of via lines.

2. The PC board module of claim 1, further comprising an Integrated Circuit (IC) device arranged on the first ground pad.

3. The PC board module of claim 2, wherein the IC device comprises an IC chip therein, and wherein the PC board module further comprises a ground plate attached to a lower surface of the IC chip and connected to a ground terminal of the IC chip, a lower surface of the ground plate being exposed outside of the IC device.

4. The PC board module of claim 3, wherein the ground plate is attached to the first ground pad with an adhesive.

5. The PC board module of claim 4, wherein the adhesive comprises a conductive adhesive.

6. The PC board module of claim 1, wherein the plurality of via lines are electrically connected to the first ground pad and the second ground pad.

7. The PC board module of claim 1, further comprising an intermediate insulator interposed between the first PC board and the second PC board to insulate the first PC board from the second PC board.

8. The PC board module of claim 7, further comprising a plurality of other via lines contained within the intermediate insulator to electrically connect the plurality of via lines arranged within the first PC board to the second ground pad.

9. The PC board module of claim 7, wherein the intermediate insulator comprises a Pressure Conductive Rubber (PCR), and wherein a portion of the intermediate insulator becomes conductive when pressed.

10. The PC board module of claim 2, wherein the first ground pad has a wider area than that of the IC device.

11. A Printed Circuit (PC) board module comprising:
a PC board having a conductive first ground pad arranged thereon;
a plurality of via holes contained within the PC board and positioned below the first ground pad;
a plurality of conductive via lines contained within the plurality of via holes; and
a second ground pad arranged below the PC board and contacting the plurality of via lines.

12. The PC board module of claim 11, wherein the first ground pad has a wider area than that of the second ground pad.

13. The PC board module of claim 11, wherein the plurality of via lines comprise solder.

14. The PC board module of claim 11, further comprising an Integrated Circuit (IC) device arranged on the first ground pad.

15. The PC board module of claim 14, wherein the IC device comprises an IC chip therein, and wherein the PC board module further comprises a ground plate attached to a lower surface of the IC chip and connected to a ground terminal of the IC chip, a lower surface of the ground plate being exposed outside of the IC device.

16. The PC board module of claim 15, wherein the ground plate is attached to the first ground pad with a conductive adhesive.
